(19) United States
(12) Patent Application Publication
(10) Pub. No.: US 2024/0282845 A1
(43) Pub. Date: Aug. 22, 2024

(54) METHOD OF MANUFACTURING SEMICONDUCTOR DEVICE

(71) Applicant: FUJI ELECTRIC CO., LTD., Kawasaki-shi (JP)

(72) Inventor: Kota OHI, Matsumoto-city (JP)

(73) Assignee: FUJI ELECTRIC CO., LTD., Kawasaki-shi (JP)

(21) Appl. No.: 18/646,397

(22) Filed: Apr. 25, 2024

Related U.S. Application Data
(63) Continuation of application No. PCT/JP2023/013842, filed on Apr. 3, 2023.

(30) Foreign Application Priority Data
May 30, 2022 (JP) 2022-087328

(51) Int. Cl. H01L 29/739; H01L 21/265; H01L 27/06; H01L 29/66; H01L 29/861

(52) U.S. Cl. CPC H01L 29/7397; H01L 21/26513; H01L 27/0629; H01L 29/66136; H01L 29/66348; H01L 29/8613

(57) ABSTRACT

A method of manufacturing the semiconductor device including: forming a trench from a top surface side of a semiconductor substrate of a first conductivity-type; burying an insulated gate electrode structure in the trench; forming a base region of a second conductivity-type at an upper part of the semiconductor substrate so as to be in contact with the trench; forming a first main electrode region of the first conductivity-type at an upper part of the base region so as to be in contact with the trench; and forming a second main electrode region of the second conductivity-type on a bottom surface side of the semiconductor substrate, where a preparation condition for at least either the base region or the second main electrode region are adjusted depending on a carbon concentration in the semiconductor substrate.

### CROSS-REFERENCE TO RELATED APPLICATION

This application is a Continuation of PCT Application No. PCT/JP2023/013842, filed on Apr. 3, 2023, and claims the priority of Japanese Patent Application No. 2022-087328, filed on May 30, 2022, the content of which are incorporated herein by reference.

### TECHNICAL FIELD

The present invention relates to methods of manufacturing semiconductor devices.

### BACKGROUND ART

Conventional semiconductor substrates (wafers) used in semiconductor devices fundamentally contain carbon as an unintentional impurity element. An impurity concentration of carbon (a carbon concentration) in a semiconductor substrate varies depending on manufacturers of wafers derived from a difference of methods of manufacturing semiconductor substrates. Seimconductor substrates made even by the same wafer manufacturer have different carbon concentrations depending on ingots of semiconductor crystals, and further depending on parts in the same ingot. A difference in carbon concentration of semiconductor substrates causes a fluctuation in the characteristics derived from the carbon concentration in the respective semiconductor substrates.

JP2021-082829A discloses a method of manufacturing a semiconductor device including a step of implanting a prescribed dose of protons into a semiconductor substrate, and a step of tempering the semiconductor substrate in accordance with a prescribed temperature profile. At least either the prescribed dose or the prescribed temperature profile is determined depending on carbon-related parameters indicating the information on a carbon concentration at least in a part of the semiconductor substrate.

WO2017/002619A1 discloses a method of equalizing a constitutional ratio of several kinds of complex defects having different levels between processed wafers after electron beam irradiation regardless of whether an impurity density of carbon or oxygen included in a base wafer as starting material varies, so as to facilitate an adjustment in variation of device characteristics.

A defect density of the crystal defects caused by the irradiation with the electron beam are adjusted to include first complex defects including holes and oxygen and second complex defects including carbon and oxygen so that a signal peak intensity of a level of the first complex defects fixed in a measurement by deep-level transient spectroscopy is to be five times or greater of a signal peak intensity of a level of the second complex defects.

### SUMMARY OF THE INVENTION

### Technical Problem

Neither JP 2021-82829 A nor WO 2017/002619 A1 takes account of adjustment of preparation conditions for a semiconductor region formed in the semiconductor substrate depending on the carbon concentration in the semiconductor substrate in order to avoid a variation in the characteristics derived from the carbon concentration of the semiconductor substrate.

In view of the foregoing problems, the present invention provides a method of manufacturing a semiconductor device capable of avoiding a variation in the characteristics derived from a carbon concentration in a semiconductor substrate.

### Solution to Problem

An aspect of the present invention inheres in a method of manufacturing a semiconductor device, including: (a) forming a trench from a top surface side of a semiconductor substrate of a first conductivity-type; (b) burying an insulated gate electrode structure in the trench; (c) forming a base region of a second conductivity-type at an upper part of the semiconductor substrate so as to be in contact with the trench; (d) forming a first main electrode region of the first conductivity-type at an upper part of the base region so as to be in contact with the trench; and (e) forming a second main electrode region of the second conductivity-type on a bottom surface side of the semiconductor substrate, wherein a preparation condition for at least either the base region or the second main electrode region is adjusted depending on a carbon concentration in the semiconductor substrate.

### BRIEF DESCRIPTION OF THE DRAWINGS

FIG. 1 is a plan view illustrating an example of a semiconductor device according to a first embodiment;

FIG. 2 is a cross-sectional view as viewed from direction A-A in FIG. 1;

FIG. 3 is a graph showing a carbon concentration dependence of a collector-emitter saturation voltage;

FIG. 4 is a graph showing a carbon concentration dependence of a turn-off loss;

FIG. 5 is a graph showing a carbon concentration dependence of a diode forward voltage;

FIG. 6 is a graph showing a carbon concentration dependence of a switching loss during a reverse recovery operation;

FIG. 7 is another graph showing the carbon concentration dependence of the collector-emitter saturation voltage;

FIG. 8 is another graph showing the carbon concentration dependence of the turn-off loss;

FIG. 9 is still another graph showing the carbon concentration dependence of the collector-emitter saturation voltage;

FIG. 10 is still another graph showing the carbon concentration dependence of the turn-off loss;

FIG. 11 is a cross-sectional view for explaining an example of a method of manufacturing the semiconductor device according to the first embodiment;

FIG. 12 is a cross-sectional view continued from FIG. 11, for explaining the example of the method of manufacturing the semiconductor device according to the first embodiment;

FIG. 13 is a cross-sectional view continued from FIG. 12, for explaining the example of the method of manufacturing the semiconductor device according to the first embodiment;

FIG. 14 is a cross-sectional view continued from FIG. 13, for explaining the example of the method of manufacturing the semiconductor device according to the first embodiment;

FIG. 15 is a cross-sectional view continued from FIG. 14, for explaining the example of the method of manufacturing the semiconductor device according to the first embodiment;

FIG. 16 is a cross-sectional view continued from FIG. 15, for explaining the example of the method of manufacturing the semiconductor device according to the first embodiment;

FIG. 17 is a cross-sectional view continued from FIG. 16, for explaining the example of the method of manufacturing the semiconductor device according to the first embodiment;

FIG. 18 is a cross-sectional view continued from FIG. 17, for explaining the example of the method of manufacturing the semiconductor device according to the first embodiment; and

FIG. 19 is a cross-sectional view continued from FIG. 18, for explaining the example of the method of manufacturing the semiconductor device according to the first embodiment.

### DETAILED DESCRIPTION

With reference to the drawings, first and second embodiments of the present invention will be described below.

In the drawings, the same or similar elements are indicated by the same or similar reference numerals. The drawings are schematic, and it should be noted that the relationship between thickness and planer dimensions, the thickness proportion of each layer, and the like are different from real ones. Accordingly, specific thicknesses or dimensions should be determined with reference to the following description. Moreover, in some drawings, portions are illustrated with different dimensional relationships and proportions.

In the following description, a “first main electrode region” and a “second main electrode region” are a main electrode region of a semiconductor element, in which a main current flows in or out. The first main electrode region is assigned to a semiconductor region which is an emitter region or a collector region in an insulated-gate bipolar transistor (IGBT). The first main electrode region is assigned to a semiconductor region which is a source region or a drain region in a field-effect transistor (FET) or a static induction transistor (SIT). The first main electrode region is assigned to a semiconductor region which is an anode region or a cathode region in a static induction (SI) thyristor or a gate turn-off (GTO) thyristor. The second main electrode region is assigned to a semiconductor region which is not assigned as the first main electrode region and will be the emitter region or the collector region in the IGBT, the source region or the drain region in the FET or the SIT, and the anode region or the cathode region in the SI thyristor or the GTO thyristor. That is, when the first main electrode region is the source region, the second main electrode region means the drain region. When the first main electrode region is the emitter region, the second main electrode region means the collector region. When the first main electrode region is the anode region, the second main electrode region means the cathode region. A “main electrode region” is described in the specification, the main electrode region comprehensively means any one of the first main electrode region and the second main electrode region.

Further, definitions of directions such as an up-and-down direction in the following description are merely definitions for convenience of understanding, and are not intended to limit the technical ideas of the present invention. For example, as a matter of course, when the subject is observed while being rotated by 90°, the subject is understood by converting the up-and-down direction into the right-and-left direction. When the subject is observed while being rotated by 180°, the subject is understood by inverting the up-and-down direction.

Further, in the following description, there is exemplified a case where a first conductivity-type is an n-type and a second conductivity-type is a p-type. However, the relationship of the conductivity types may be inverted to set the first conductivity-type to the p-type and the second conductivity-type to the n-type. Further, a semiconductor region denoted by the symbol “n” or “p” attached with “+” indicates that such semiconductor region has a relatively high impurity concentration or a relatively low specific resistance as compared to a semiconductor region denoted by the symbol “n” or “p” without “+”. A semiconductor region denoted by the symbol “n” or “p” attached with “−” indicates that such semiconductor region has a relatively low impurity concentration or a relatively high specific resistance as compared to a semiconductor region denoted by the symbol “n” or “p” without “−”. However, even when the semiconductor regions are denoted by the same reference symbols “n” and “n”, it is not indicated that the semiconductor regions have exactly the same impurity concentration or the same specific resistance.

### First Embodiment

### <Structure of Semiconductor Device>

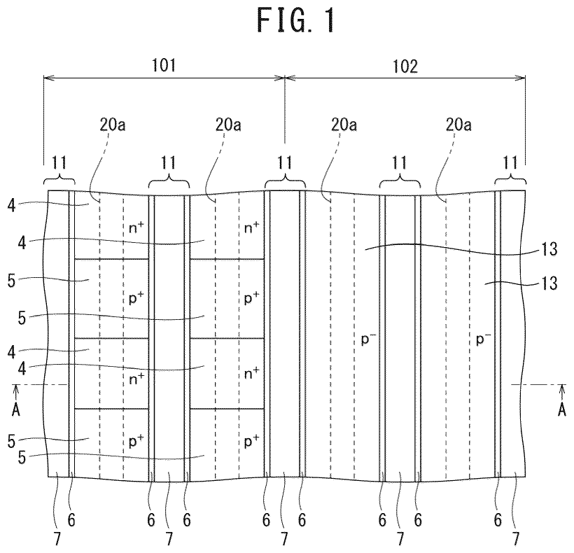

FIG. 1 is a plan view illustrating a part of an active region of a semiconductor device according to the first embodiment as viewed from the top surface (front surface) side. The semiconductor device according to the first embodiment includes a transistor part 101 including a transistor element such as an IGBT and a diode part 102 including a diode element, which are integrated in the common semiconductor chip, as illustrated in FIG. 1. The semiconductor device according to the first embodiment is, for example, a reverse conductive IGBT (RC-IGBT) including the IGBT that is the transistor part 101 and a free-wheeling diode (FWD) that is the diode part 102 connected in antiparallel to the IGBT on the common semiconductor chip. The transistor part 101 and the diode part 102 may be repeatedly and alternately arranged in the right-left direction in FIG. 1.

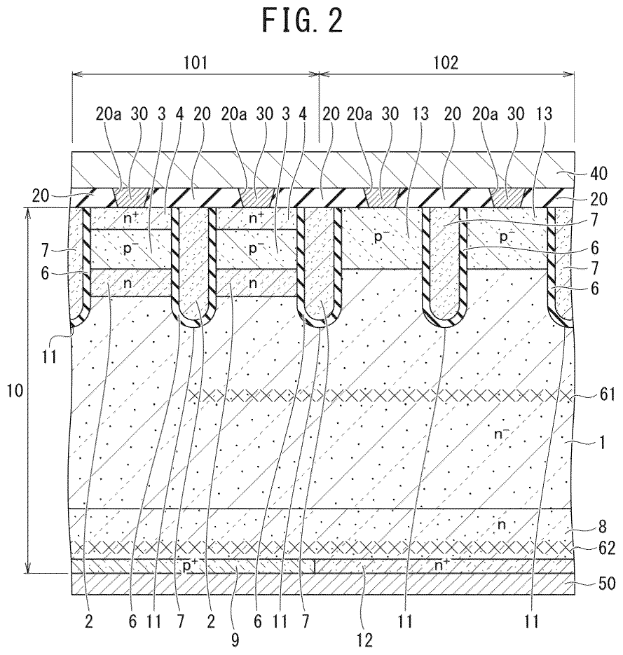

FIG. 2 is a cross-sectional view taken along line A-A passing across the transistor part 101 and the diode part 102 in FIG. 1. As illustrated in FIG. 2, the semiconductor device according to the first embodiment includes a semiconductor substrate 10. The semiconductor substrate 10 is a silicon (Si) wafer including single-crystal silicon manufactured by a magnetic field-applied Czochralski method (a MCZ method), for example.

The semiconductor substrate 10 includes a drift layer 1 of a first conductivity-type (n⁻-type). An accumulation layer 2 of n-type having a higher impurity concentration than the drift layer 1 is provided on the top surface side of the drift layer 1 in the transistor part 101. The bottom surface of the accumulation layer 2 is in contact with the top surface of the drift layer 1. The provision of the accumulation layer 2 can improve an injection enhancement effect (an IE effect) of carriers, so as to decrease an ON voltage.

A base region 3 of a second conductivity-type (p⁻-type) is provided on the top surface side of the accumulation layer 2 in the transistor part 101. The bottom surface of the base region 3 is in contact with the top surface of the accumulation layer 2. A first main electrode region (an emitter region) 4 of n⁺-type is provided on the top surface side of the base region 3. The bottom surface of the emitter region 4 is in contact with the top surface of the base region 3. The emitter region 4 has a higher impurity concentration than each of the drift layer 1 and the accumulation layer 2.

No accumulation layer as in the transistor part 101 is provided on the top surface side of the drift layer 1 in the diode part 102. An accumulation layer of n-type having a higher impurity concentration than the drift layer 1 may be provided on the top surface side of the drift layer 1 in the diode part 102. An anode region 13 of p-type is provided on the top surface side of the drift layer 1 in the diode part 102. The bottom surface of the anode region 13 is in contact with the top surface of the drift layer 1. The anode region 13 is deposited up to the top surface of the semiconductor substrate 10. The anode region 13 may have the same depth and the same impurity concentration as the base region 3 in the transistor part 101.

A plurality of trenches 11 are provided separately from each other and dug from the top surface of the semiconductor substrate 10 in the depth direction in each of the transistor part 101 and the diode part 102. The trenches 11 in the transistor part 101 penetrate the emitter region 4, the base region 3, and the accumulation layer 2 to reach the drift layer 1. The side surfaces (the side walls) of the respective trenches 11 are in contact with the respective side surfaces of the emitter region 4, the base region 3, and the accumulation layer 2. The trenches 11 in the diode part 102 penetrate the anode region 13 to reach the drift layer 1. The side surfaces of the respective trenches 11 are in contact with the side surfaces of the anode region 13.

A mesa part implemented by the upper part of the semiconductor substrate 10 is provided between the respective trenches 11 next to each other in the direction in which the trenches 11 are arranged in parallel. The mesa part is a region of the semiconductor substrate 10 interposed between the respective trenches 11 next to each other, and is located at a position higher than the deepest part of the respective trenches 11. The mesa part in the transistor part 101 is provided with the upper part of the drift layer 1, the accumulation layer 2, the base region 3, and the emitter region 4. The mesa part in the diode part 102 is provided with the upper part of the drift layer 1 and the anode region 13.

A gate insulating film 6 is provided to cover the bottom and the side surfaces of the respective trenches 11. The gate insulating film 6 as used herein can be a single-layer film of a silicon dioxide (SiO₂) film, a silicon oxynitride (SiON) film, a strontium oxide (SrO) film, a silicon nitride (Si₃N₄) film, an aluminum oxide (Al₂O₃) film, a magnesium oxide (MgO) film, an yttrium oxide (Y₂O₃) film, a hafnium oxide (HfO₂) film, a zirconium oxide (ZrO₂) film, a tantalum oxide (Ta₂O₅) film, or a bismuth oxide (Bi₂O₃) film, or a composite film including some of the above films stacked on one another.

A gate electrode 7 is buried inside the respective trenches 11 with the gate insulating film 6 interposed. The gate insulating film 6 and the gate electrode 7 implement an insulated gate electrode structure (6, 7). The gate electrode 7 as used herein can be made of a polysilicon layer (a doped polysilicon layer) heavily doped with impurity ions such as phosphorus (P) or boron (B), for example.

Some of the plural insulated gate electrode structures (6, 7) in the transistor part 101 are each a gate trench part connected to a gate runner, while the rest of the insulated gate electrode structures (6, 7) may each be a dummy trench part not connected to the gate runner. The respective insulated gate electrode structures (6, 7) in the diode part 102 may be a dummy trench part not connected to the gate runner.

As illustrated in FIG. 1, the trenches 11 have straight (stripe-shaped) parts extending in one direction (the upper-lower direction in FIG. 1) parallel to each other in the planar pattern. The anode region 13 in the diode part 102 includes straight (stripe-shaped) parts extending parallel to the extending direction of the trenches 11. A p⁺-type contact region 5 and the n⁺-type emitter region 4 are alternately and repeatedly arranged in the transistor part 101 in a direction parallel to the extending direction (the longitudinal direction) of the respective trenches 11. The contact region 5 is in contact with the emitter region 4. The contact region 5 is provided on the top surface side of the base region 3 illustrated in FIG. 2. The bottom surface of the contact region 5 is in contact with the top surface of the base region 3. The contact region 5 has a higher impurity concentration than the base region 3.

As illustrated in FIG. 2, an interlayer insulating film 20 is deposited on the top surfaces of the semiconductor substrate 10 and the respective insulated gate electrode structures (6, 7). The interlayer insulating film 20 is a single-layer film of a silicon oxide film (a SiO₂ film) without containing phosphorus (P) or boron (B) which is referred to as a non-doped silicate glass (NSG) film, a phosphosilicate glass film (a PSG film), a borosilicate glass (a BSG film), a borophosphosilicate glass film (a BPSG film), a silicon nitride film (a Si₃N₄ film), or a high-temperature oxide film (a HTO film), or a stacked-layer film including some of the above films stacked on one another.

The interlayer insulating film 20 located on the mesa part of the semiconductor substrate 10 is provided with contact holes 20a penetrating the interlayer insulating film 20. A contact plug 30 made of tungsten (W) and the like is buried in the respective contact holes 20a with a titanium silicide (TiSi₂) layer and a barrier metal film including titanium nitride (TiN) (not illustrated) interposed. The bottom surfaces of the contact plugs 30 in the transistor part 101 are in contact with the respective top surfaces of the emitter region 4 and the contact region 5. The bottom surfaces of the contact plugs 30 in the diode part 102 are in contact with the top surface of the anode region 13.

A front-surface electrode 40 is deposited on the interlayer insulating film 20. The front-surface electrode 40 in the transistor part 101 is electrically connected to the emitter region 4 and the contact region 5 via the contact plugs 30 so as to serve as an emitter electrode. The front-surface electrode 40 in the diode part 102 is electrically connected to the anode region 13 via the contact plugs 30 so as to serve as an anode electrode. A high-concentration p-type region may be provided between the contact plug 30 and the anode region 13. The front-surface electrode 40 as used herein can include metal such as aluminum (Al), an Al alloy, or copper (Cu). Examples of Al alloys include an Al-silicon (Si) alloy, an Al—Si—Cu alloy, and an Al—Cu alloy.

FIG. 1 omits the illustration of the interlayer insulating film 20, the contact plugs 30, and the front-surface electrode 40 illustrated in FIG. 2. FIG. 1 schematically indicates, by the broken lines, the positions of the contact holes 20a provided in the interlayer insulating film 20 illustrated in FIG. 2. The contact holes 20a have straight (stripe-shaped) parts extending parallel to the longitudinal direction of the respective trenches 11 in the planar pattern. The contact holes 20a in the transistor part 101 are provided on the top surface side of each of the emitter region 4 and the contact region 5. The contact holes 20a in the diode part 102 are provided on the top surface side of the anode region 13.

A field-stop (FS) layer 8 of n-type having a higher impurity concentration than the drift layer 1 is deposited on the bottom surface side of the drift layer 1 in each of the transistor part 101 and the diode part 102. The top surface of the FS layer 8 is in contact with the bottom surface of the drift layer 1. The provision of the FS layer 8 prevents a depletion layer expanding from the bottom surface side of the base region 3 and the anode region 13 from reaching a second main electrode region (a collector region) 9 described below and the cathode region 12.

The p⁺-type collector region 9 is deposited on the bottom surface side of the FS layer 8 in the transistor part 101. The top surface of the collector region 9 is in contact with the bottom surface of the FS layer 8. The collector region 9 has a higher impurity concentration than the base region 3. The n⁺-type cathode region 12 having a higher impurity concentration than the FS layer 8 is deposited on the bottom surface side of the FS layer 8 in the diode part 102. The top surface of the cathode region 12 is in contact with the bottom surface of the FS layer 8. The cathode region 12 is deposited to have the same depth as the collector region 9. The side surface of the cathode region 12 is in contact with the side surface of the collector region 9.

A rear-surface electrode 50 is deposited on the bottom surface side of the collector region 9 and the cathode region 12. The rear-surface electrode 50 is, for example, made of a single film of gold (Au) or a metallic film including titanium (Ti), nickel (Ni), and gold (Au) stacked in this order. The rear-surface electrode 50 serves as a collector electrode in the transistor part 101, and serves as a cathode electrode in the diode part 102.

As illustrated in FIG. 2, a life-time control region 61 is provided inside the drift layer 1. The life-time control region 61 is arranged along the entire region of the diode part 102 and further extends to reach a part of the transistor part 101. The life-time control region 61 may be provided only in the diode part 102.

A life-time control region 62 is provided in the FS layer 8. The life-time control region 62 is arranged entirely and evenly along the transistor part 101 and the diode part 102, for example.

The respective life-time control regions 61 and 62 are composed of crystal defects (point defects) made by helium (He) or proton (hydrogen), for example, injected as a life-time killer. The provision of the respective life-time control regions 61 and 62 can improve and enhance the characteristics of the semiconductor device, such as a diode forward voltage Vf of the FWD.

The semiconductor device according to the first embodiment during the operation applies a positive voltage to the rear-surface electrode 50 in the transistor part 101 while using the front-surface electrode 40 as a ground potential, and causes an inversion layer (a channel) to be formed in the base region 3 toward the side surface of the respective trenches 11 so as to be in the ON-state when a positive voltage of a threshold or greater is applied to the gate electrode 7. In the ON-state, a current flows from the rear-surface electrode 50 toward the front-surface electrode 40 through the collector region 9, the FS layer 8, the drift layer 1, the accumulation layer 2, the inversion layer of the base region 3, and the emitter region 4.

When the voltage applied to the gate electrode 7 is smaller than the threshold, the semiconductor device is led to be in the OFF-state since no inversion layer is formed in the base region 3, and no current flows from the rear-surface electrode 50 toward the front-surface electrode 40. The diode part 102 causes a flow of a reflux current flowing in the opposite direction when the transistor part 101 is turned off.

The semiconductor substrate 10 as a base wafer illustrated in FIG. 2 contains an unintentionally-added impurity element such as carbon derived from a process of preparing the semiconductor substrate 10. An impurity concentration of carbon (a carbon concentration) in the semiconductor substrate 10 is presumed to be in a range of about 1×10¹⁵ atoms/cm³ or greater and 3.5×10¹⁵ atoms/cm³ or less, but is not limited to this range. The carbon concentration in the semiconductor substrate 10 can be measured by secondary ion mass spectrometry (SIMS), for example.

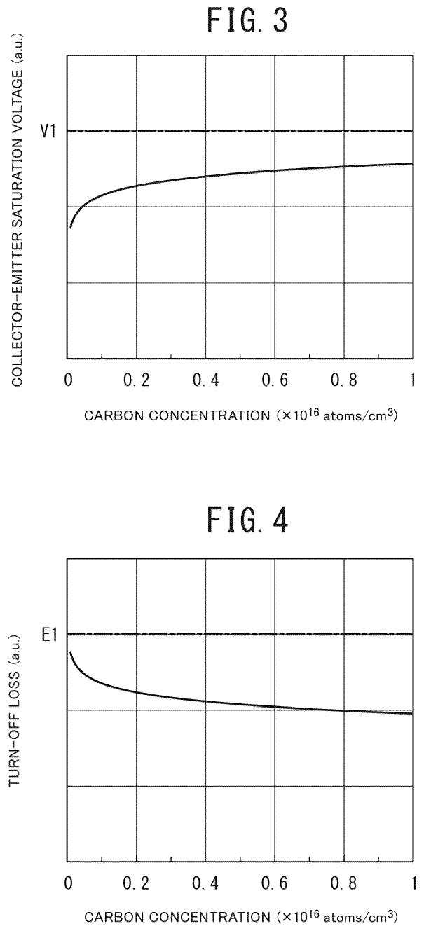

The characteristics of the IGBT (referred to below as the “IGBT characteristics”) implementing the transistor part 101 and the characteristics of the FWD (referred to below as the “diode characteristics”) implementing the diode part 102 vary depending on the carbon concentration in the semiconductor substrate 10. FIG. 3 is a graph showing a relation between the carbon concentration in the semiconductor substrate 10 and a collector-emitter saturation voltage Vce (sat) that is one of the IGBT characteristics. As indicated by the solid line in FIG. 3, the collector-emitter saturation voltage Vce (sat) is decreased as the carbon concentration in the semiconductor substrate 10 is lower. Further, the collector-emitter saturation voltage Vce (sat) is sharply changed and the decreased amount is larger in the range in which the carbon concentration in the semiconductor substrate 10 is lower. The dash-dotted line in FIG. 3 indicates a maximum standard value V1 of the collector-emitter saturation voltage Vce (sat). The maximum standard value V1 can be determined as appropriate depending on a rated current of the semiconductor device according to the first embodiment, for example. The collector-emitter saturation voltage Vce (sat) is adjusted to be the maximum standard value V1 or smaller.

FIG. 4 is a graph showing a relation between the carbon concentration in the semiconductor substrate 10 and a turn-off loss Eoff that is one of the IGBT characteristics. As indicated by the solid line in FIG. 4, the turn-off loss Eoff is increased as the carbon concentration in the semiconductor substrate 10 is lower. Further, the turn-off loss Eoff is sharply changed and the increased amount is larger in the range in which the carbon concentration in the semiconductor substrate 10 is lower. Namely, the collector-emitter saturation voltage Vce (sat) shown in FIG. 3 and the turn-off loss Eoff shown in FIG. 4 have a trade-off relation. The dash-dotted line in FIG. 4 indicates a maximum standard value E1 of the turn-off loss Eoff. The maximum standard value E1 can be determined as appropriate depending on the rated current of the semiconductor device according to the first embodiment, for example. The turn-off loss Eoff is adjusted to be the maximum standard value E1 or smaller.

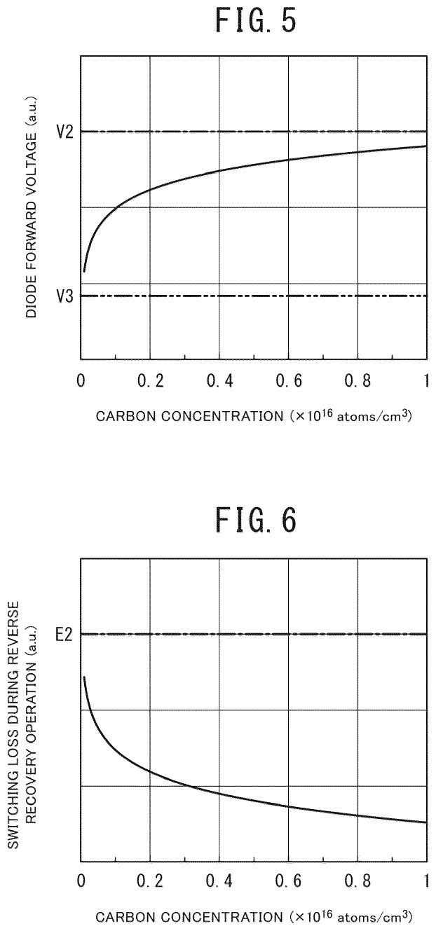

FIG. 5 is a graph showing a relation between the carbon concentration in the semiconductor substrate 10 and a diode forward voltage Vf that is one of the diode characteristics. As indicated by the solid line in FIG. 5, the diode forward voltage Vf is decreased as the carbon concentration in the semiconductor substrate 10 is lower. Further, the diode forward voltage Vf is sharply changed and the decreased amount is larger in the range in which the carbon concentration in the semiconductor substrate 10 is lower. The dash-dotted line in FIG. 5 indicates a maximum standard value V2 of the diode forward voltage Vf, and the dashed and double-dotted line indicates a minimum standard value V3 of the diode forward voltage Vf. The maximum standard value V2 and the minimum standard value V3 can be determined as appropriate depending on the rated current of the semiconductor device according to the first embodiment, for example. The diode forward voltage Vf is adjusted in a range between the maximum standard value V2 and the minimum standard value V3.

FIG. 6 is a graph showing a relation between the carbon concentration in the semiconductor substrate 10 and a switching loss Err during a reverse recovery operation that is one of the diode characteristics. As indicated by the solid line in FIG. 6, the switching loss Err during the reverse recovery operation is increased as the carbon concentration in the semiconductor substrate 10 is lower. Further, the switching loss Err during the reverse recovery operation is sharply changed and the increased amount is larger in the range in which the carbon concentration in the semiconductor substrate 10 is lower. Namely, the diode forward voltage Vf shown in FIG. 5 and the switching loss Err during the reverse recovery operation shown in FIG. 6 have a trade-off relation. The dash-dotted line in FIG. 6 indicates a maximum standard value E2 of the switching loss Err during the reverse recovery operation. The maximum standard value E2 can be determined as appropriate depending on the rated current of the semiconductor device according to the first embodiment, for example. The switching loss Err during the reverse recovery operation is adjusted to be the maximum standard value E2 or smaller.

As described above, the carbon concentration in the semiconductor substrate 10 can vary depending on manufacturers of wafers (semiconductor substrates) derived from a difference between methods of manufacturing the semiconductor substrates, for example. If the variation in the carbon concentration in the semiconductor substrate 10 is large, the turn-off loss Eoff shown in FIG. 4 is increased more than the maximum standard value E1 when, for example, the semiconductor substrate 10 having a low carbon concentration is used, which may cause faults of products. Similarly, the collector-emitter saturation voltage Vce (sat) shown in FIG. 3 is increased more than the maximum standard value V1 when the semiconductor substrate 10 having a high carbon concentration is used, which may cause faults of products.

To avoid such a variation in the characteristics derived from the carbon concentration in the semiconductor substrate 10, a method of manufacturing the semiconductor device according to the first embodiment preliminarily obtains the carbon concentration in the semiconductor substrate 10 to determine (adjust) the conditions for preparing the collector region 9 in the transistor part 101 depending on the obtained carbon concentration in the semiconductor substrate 10. The preparation conditions for the collector region 9 include an adjustment of dose amount of ion implantation for forming the collector region 9, for example. The adjusted dose amount of the ion implantation can be set within about ±10% of the dose amount before the adjustment.

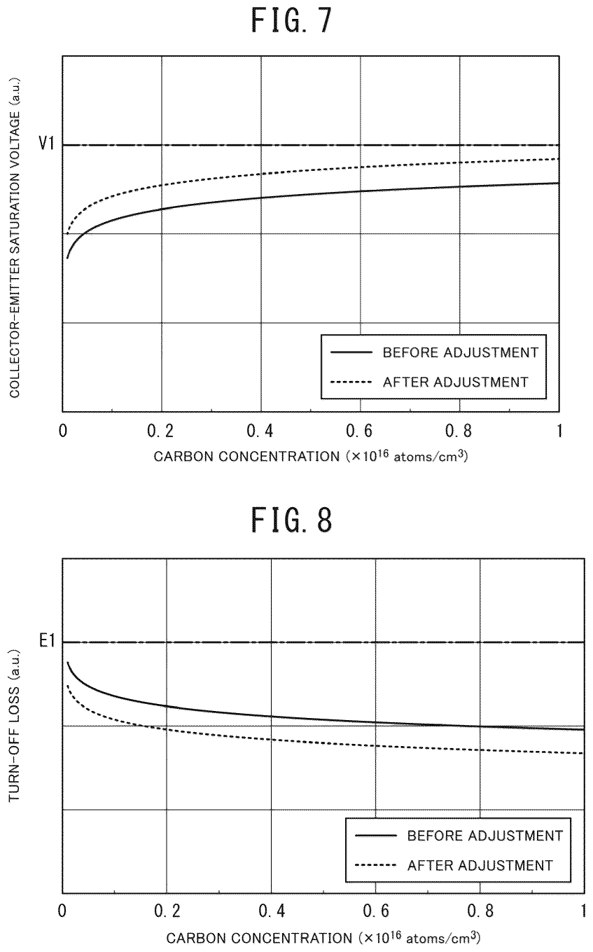

FIG. 7 is a graph showing a relation between the carbon concentration in the semiconductor substrate 10 and the collector-emitter saturation voltage Vce (sat) before and after the adjustment of the dose amount of the ion implantation for forming the collector region 9. The solid line in FIG. 7 indicates the collector-emitter saturation voltage Vce (sat) before the dose amount of the ion implantation for forming the collector region 9 is adjusted, and the dotted line in FIG. 7 indicates the collector-emitter saturation voltage Vce (sat) after the dose amount of the ion implantation for forming the collector region 9 is adjusted to be low. As illustrated in FIG. 7, the collector-emitter saturation voltage Vce (sat) is increased as the dose amount of the ion implantation for forming the collector region 9 is adjusted to be lower, while the collector-emitter saturation voltage Vce (sat) is decreased as the dose amount of the ion implantation for forming the collector region 9 is adjusted to be higher.

FIG. 8 is a graph showing a relation between the carbon concentration in the semiconductor substrate 10 and the turn-off loss Eoff before and after the adjustment of the dose amount of the ion implantation for forming the collector region 9. The solid line in FIG. 8 indicates the turn-off loss Eoff before the dose amount of the ion implantation for forming the collector region 9 is adjusted, and the dotted line in FIG. 8 indicates the turn-off loss Eoff after the dose amount of the ion implantation for forming the collector region 9 is adjusted to be low. As illustrated in FIG. 8, the turn-off loss Eoff is decreased as the dose amount of the ion implantation for forming the collector region 9 is adjusted to be lower, while the turn-off loss Eoff is increased as the dose amount of the ion implantation for forming the collector region 9 is adjusted to be higher.

The method of manufacturing the semiconductor device according to the first embodiment adjusts the dose amount of the ion implantation for forming the collector region 9 to be lower as the carbon concentration in the semiconductor substrate 10 is lower, so as to decrease the turn-off loss Eoff and increase the collector-emitter saturation voltage Vce (sat). For example, when the carbon concentration in the semiconductor substrate 10 is relatively low and the turn-off loss Eoff thus could exceed the maximum standard value E1, the dose amount of the ion implantation for forming the collector region 9 is adjusted to be low so that the turn-off loss Eoff is decreased to the maximum standard value E1 or smaller and the collector-emitter saturation voltage Vce (sat) is increased but regulated to be the maximum standard value V1 or smaller.

When the carbon concentration in the semiconductor substrate 10 is relatively high and the collector-emitter saturation voltage Vce (sat) thus could exceed the maximum standard value V1, the dose amount of the ion implantation for forming the collector region 9 is adjusted to be high so that the collector-emitter saturation voltage Vce (sat) is decreased to the maximum standard value V1 or smaller and the turn-off loss Eoff is increased but regulated to be the maximum standard value E1 or smaller.

For example, a determination is made whether the carbon concentration in the semiconductor substrate 10 is a predetermined threshold or greater, and the dose amount of the ion implantation for forming the collector region 9 is adjusted in accordance with the determination result. The predetermined threshold can be set depending on the rated current, the maximum standard value V1 of the collector-emitter saturation voltage Vce (sat), and the maximum standard value E1 of the turn-off loss Eoff of the semiconductor device according to the first embodiment, for example.

For example, when the carbon concentration in the semiconductor substrate 10 is the predetermined threshold or greater, the dose amount of the ion implantation for forming the collector region 9 is set to a first dose amount before adjustment. When the carbon concentration in the semiconductor substrate 10 is less than the predetermined threshold, the dose amount of the ion implantation for forming the collector region 9 is adjusted to a second dose amount greater than the first dose amount. Alternatively, several predetermined thresholds may be set and each compared with the carbon concentration in the semiconductor substrate 10 so that the dose amount is adjusted at several levels.

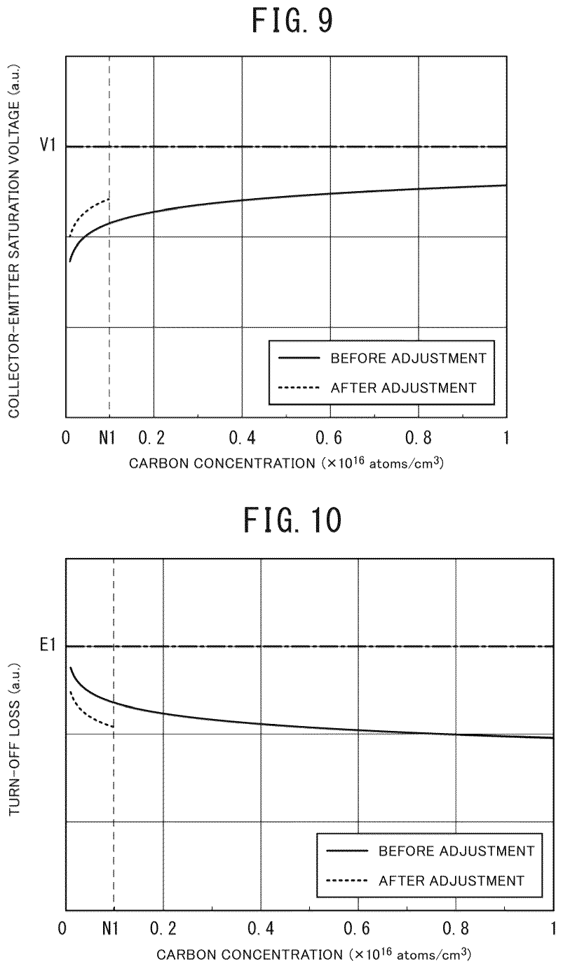

FIG. 9 is a graph showing a relation between the carbon concentration in the semiconductor substrate 10 and the collector-emitter saturation voltage Vce (sat) before and after the adjustment of the dose amount of the ion implantation for forming the collector region 9 when a predetermined threshold N1 is set with respect to the carbon concentration in the semiconductor substrate 10. FIG. 10 is a graph showing a relation between the carbon concentration in the semiconductor substrate 10 and the turn-off loss Eoff before and after the adjustment of the dose amount of the ion implantation for forming the collector region 9 when the predetermined threshold N1 is set with respect to the carbon concentration in the semiconductor substrate 10. The predetermined threshold N1 in FIG. 9 and FIG. 10 is set to about 0.1×10¹⁶ atoms/cm³, but is not limited to this value.

As illustrated in FIG. 9 and FIG. 10, when the carbon concentration in the semiconductor substrate 10 is the predetermined threshold N1 or greater, the dose amount of the ion implantation for forming the collector region 9 is kept at the first dose amount before the adjustment (indicated by the solid line in FIG. 9 and FIG. 10). When the carbon concentration in the semiconductor substrate 10 is less than the predetermined threshold N1, the dose amount of the ion implantation for forming the collector region 9 is set to the second dose amount lower than the first dose amount (indicated by the dotted line in FIG. 9 and FIG. 10). This adjustment can decrease the turn-off loss Eoff while increasing but regulating the collector-emitter saturation voltage Vce (sat) to be the maximum standard value V1 or smaller in the range in which the carbon concentration in the semiconductor substrate 10 is less than the predetermined threshold N1, as illustrated in FIG. 9 and FIG. 10.

### <Method of Manufacturing Semiconductor Device>

An example of the method of manufacturing the semiconductor device according to the first embodiment is described below. The method of manufacturing the semiconductor device described below is one of examples, and it should be understood that the semiconductor device according to the first embodiment can be achieved by various manufacturing methods including modified examples within the scope of the appended claims.

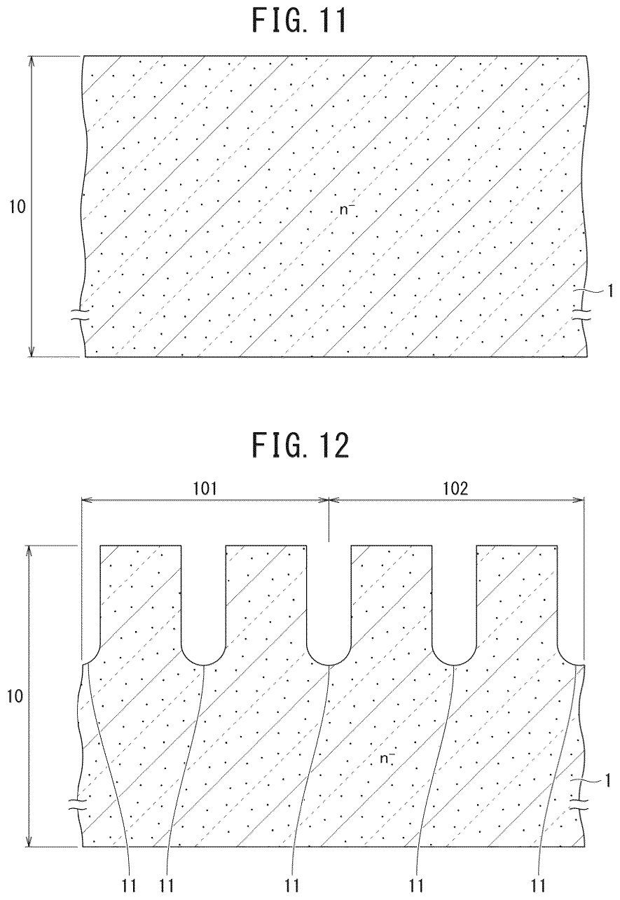

First, as illustrated in FIG. 11, the semiconductor substrate 10 of the first conductivity-type (n⁻-type) is prepared. The semiconductor substrate 10 is a Si wafer including single-crystal Si manufactured by a magnetic field-applied Czochralski method (a MCZ method), for example. Before a step of forming the collector region 9 described below, the carbon concentration in the semiconductor substrate 10 is preliminarily obtained. The carbon concentration in the semiconductor substrate 10 may be obtained either by measurement or through a wafer manufacturer. The carbon concentration in the semiconductor substrate 10 can be measured by secondary ion mass spectrometry (SIMS), for example.

Next, a part of the drift layer 1 is selectively removed from the top surface side of the semiconductor substrate 10 by photolithography and dry etching. The plurality of trenches 11 are thus formed in the upper part of the semiconductor substrate 10, as illustrated in FIG. 12.

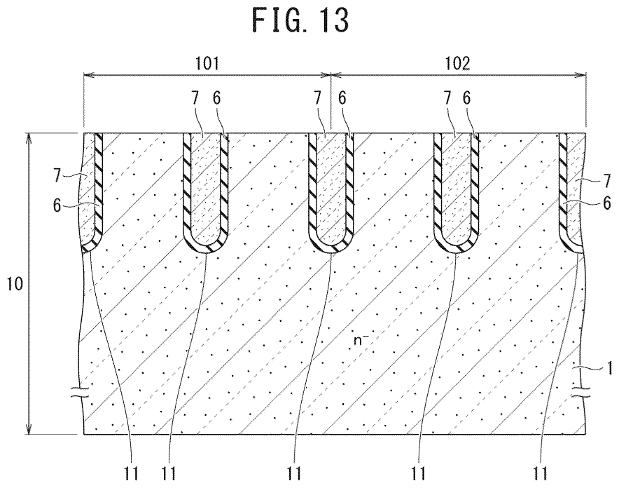

Next, the gate insulating film 6 is formed on the bottom and the side surfaces of the respective trenches 11 by a thermal oxidation method or a chemical vapor deposition (CVD) method, for example. Next, a polysilicon film (a doped polysilicon film) heavily doped with impurity ions such as phosphorus (P) or boron (B) is deposited to fill the inside of the respective trenches 11 with the gate insulating film 6 interposed. The polysilicon film and the gate insulating film 6 on the semiconductor substrate 10 are then selectively removed by photolithography and dry etching. The insulated gate electrode structure (6, 7) implemented by the gate insulating film 6 and the gate electrode 7 of the polysilicon film is thus formed in the respective trenches 11, as illustrated in FIG. 13.

Next, p-type impurity ions such as boron (B) are implanted into the entire top surface of the drift layer 1 so as to simultaneously form the p⁻-type base region 3 in the transistor part 101 and the p⁻-type anode region 13 in the diode part 102. The photoresist film is then removed.

Next, a photoresist film is applied on the top surface of the drift layer 1, and is then delineated by photolithography. Using the delineated photoresist film as a mask for ion implantation, n-type impurity ions such as phosphorus (P) or arsenic (As) are implanted so as to form the n-type accumulation layer 2 in the transistor part 101. The photoresist film is then removed.

Next, a photoresist film is applied on the top surface of the drift layer 1, and is then delineated by photolithography. Using the delineated photoresist film as a mask for ion implantation, p-type impurity ions such as boron (B) are implanted so as to form the p⁺-type contact region 5 in the transistor part 101 (refer to FIG. 1). The photoresist film is then removed.

Next, a photoresist film is applied on the top surface of the drift layer 1, and is then delineated by photolithography. Using the delineated photoresist film as a mask for ion implantation, n-type impurity ions are implanted so as to form the n⁺-type emitter region 4 in the transistor part 101. The photoresist film is then removed. The order of the ion implantation for forming the accumulation layer 2, the ion implantation for forming each of the base region 3 and the anode region 13, the ion implantation for forming the emitter region 4, and the ion implantation for forming the contact region 5 is not limited to the case described above and can be changed as appropriate.

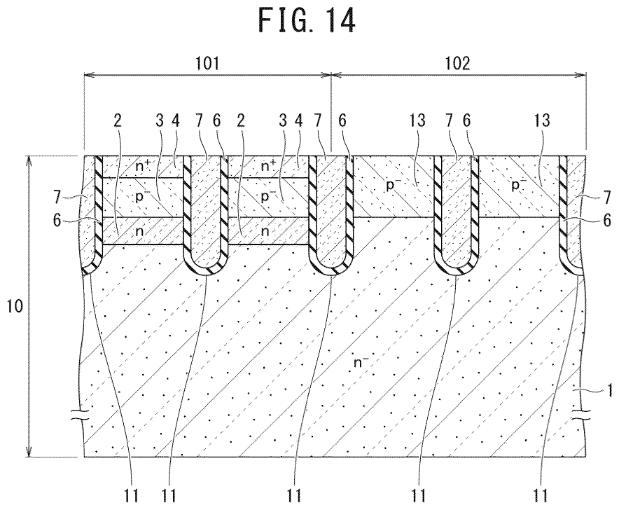

Next, the impurity ions implanted into the semiconductor substrate 10 are activated by annealing. The n-type accumulation layer 2, the p⁻-type base region 3, the n⁺-type emitter region 4, and the p⁺-type contact region 5 (refer to FIG. 1) are thus provided in the upper part of the semiconductor substrate 10 in the transistor part 101, as illustrated in FIG. 14. Similarly, the p-type anode region 13 is provided in the upper part of the semiconductor substrate 10 in the diode part 102.

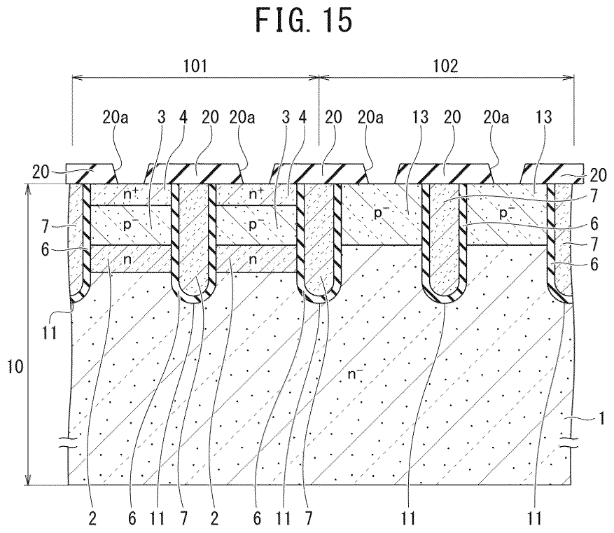

Next, the interlayer insulating film 20 is formed by the CVD method and the like on the respective top surfaces of the insulated gate electrode structures (6, 7), the emitter region 4, the contact region 5, and the anode region 13. A photoresist film is then applied on the top surface of the interlayer insulating film 20, and is delineated by photolithography. Using the delineated photoresist film as a mask for etching, the interlayer insulating film 20 is party and selectively removed by dry etching. This step opens the contact holes 20a in the interlayer insulating film 20, as illustrated in FIG. 15.

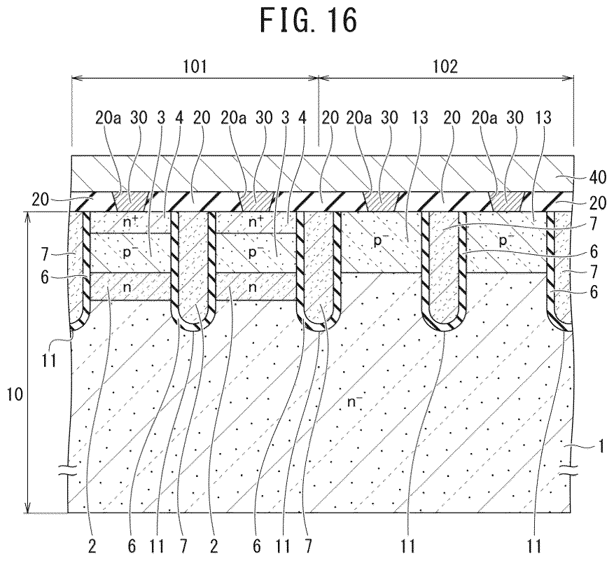

Next, the respective contact holes 20a are filled with the contact plug 30 with a barrier metal film interposed by sputtering or vapor deposition and dry etching, for example. The front-surface electrode 40 is then deposited on the top surfaces of the respective contact plugs 30 and the interlayer insulating film 20 by sputtering or vapor deposition, for example, as illustrated in FIG. 16.

Next, the semiconductor substrate 10 is ground from the bottom surface side by chemical mechanical polishing (CMP) or the like, for example, so that the thickness of the semiconductor substrate 10 is adjusted to have an intended thickness of a product. Next, n-type impurity ions such as phosphorus (P) or selenium (Se) for forming the n-type FS layer 8 are implanted into the entire bottom surface of the semiconductor substrate 10.

Next, p-type impurity ions such as boron (B) for forming the p⁺-type collector region 9 are implanted into the entire bottom surface of the semiconductor substrate 10 at a lower acceleration voltage than that upon the ion implantation executed for forming the n-type FS layer 8. As described above, the conditions for preparing the p⁺-type collector region 9, such as the dose amount of the ion implantation for forming the p⁺-type collector region 9, are adjusted depending on the carbon concentration in the semiconductor substrate 10. For example, the dose amount of the ion implantation for forming the p⁺-type collector region 9 is adjusted to be lower as the carbon concentration in the semiconductor substrate 10 is lower, and the ion implantation is then executed in accordance with the adjusted dose amount.

Next, a photoresist film is applied on the bottom surface of the drift layer 1, and is then delineated by photolithography. Using the delineated photoresist film as a mask for ion implantation, n-type impurity ions such as phosphorus (P) are implanted so as to form the n⁺-type cathode region 12.

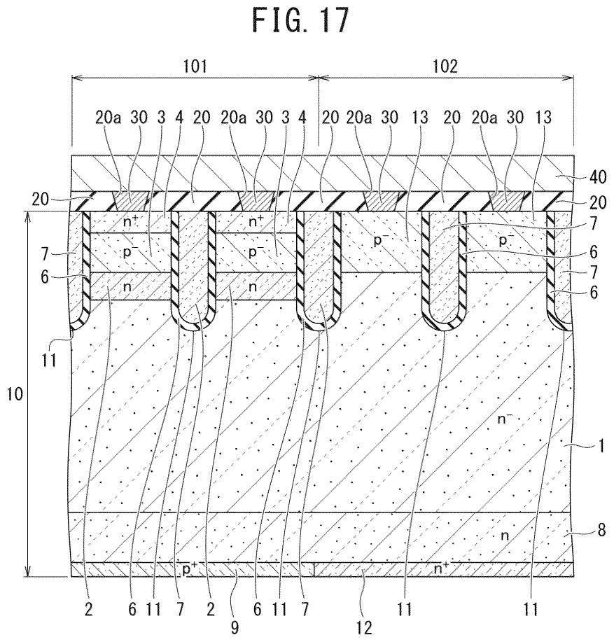

Next, the impurity ions implanted into the semiconductor substrate 10 are activated by annealing. The n-type FS layer 8 is thus formed in the lower part of the semiconductor substrate 10, as illustrated in FIG. 17. Further, the p⁺-type collector region 9 is formed in the transistor part 101, and the n⁺-type cathode region 12 is formed in the diode part 102. The order of the ion implantation for forming the FS layer 8, the ion implantation for forming the p⁺-type collector region 9, and the ion implantation for forming the n⁺-type cathode region 12 can be changed as appropriate.

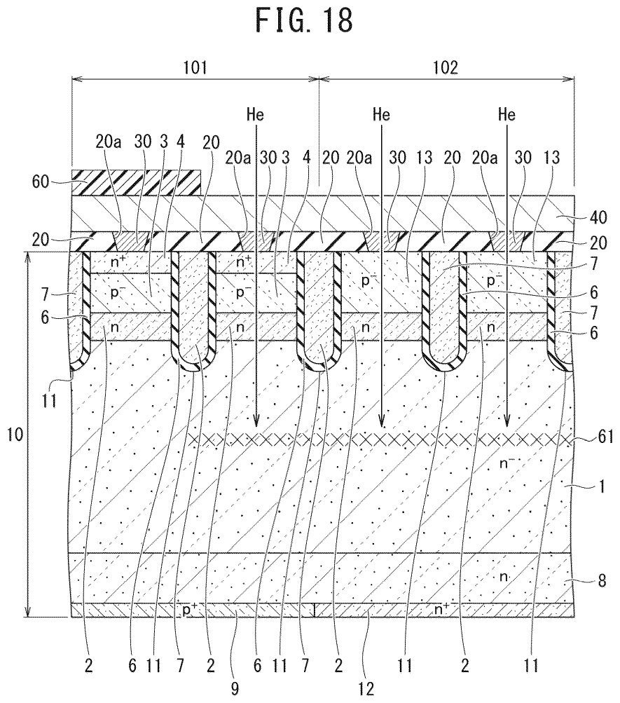

Next, the top surface of the semiconductor substrate 10 is irradiated with a particle beam of a light element such as helium (He) or proton (H) with a shielding film 60 such as aluminum used as a mask, so as to selectively form the life-time control region 61, as illustrated in FIG. 18. Alternatively, the shielding film 60 may be arranged on the bottom surface side of the semiconductor substrate 10 so as to irradiate not the top surface but the bottom surface of the semiconductor substrate 10 with the particle beam. Alternatively, the irradiation may be executed with any other particle beam such as an electron beam. The shielding film 60 is then removed.

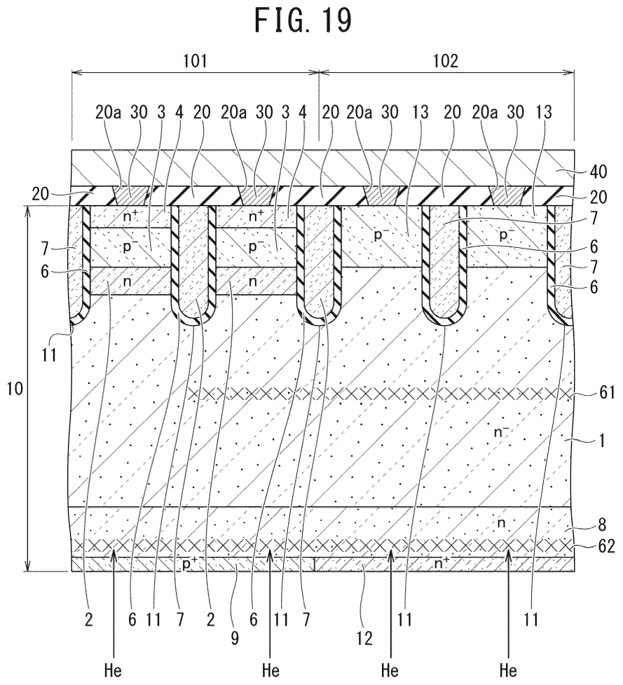

Next, the bottom surface of the semiconductor substrate 10 is irradiated with a particle beam of a light element such as helium (He) or proton (H) so as to uniformly form the life-time control region 62 inside the FS layer 8, as illustrated in FIG. 19. Alternatively, not the bottom surface but the top surface of the semiconductor substrate 10 may be irradiated with the particle beam. Alternatively, the irradiation may be executed with any other particle beam such as an electron beam. The life-time control region 62 may be formed inside the drift layer 1.

Next, annealing is executed. The annealing may be executed in an atmosphere containing hydrogen. The execution of the annealing regulates the formation of crystal defects in the respective life-time control regions 61 and 62 so as to obtain an intended life time.

Next, the rear-surface electrode 50 including gold (Au) is formed on the entire bottom surface of the semiconductor substrate 10 by sputtering or vapor deposition, for example. Thereafter, the semiconductor substrate 10 is cut (diced) into individual pieces, so as to complete the semiconductor device according to the first embodiment as illustrated in FIG. 1 and FIG. 2.

The method of manufacturing the semiconductor device according to the first embodiment preliminarily obtains the carbon concentration in the semiconductor substrate 10 so as to regulate the conditions for preparing the collector region 9 depending on the obtained carbon concentration. This can avoid a variation in the IGBT characteristics derived from the carbon concentration in the semiconductor substrate 10 regardless of the fluctuation of the carbon concentration.

The RC-IGBT, if the irradiation conditions of the light element upon the formation of the respective life-time control regions 61 and 62 are adjusted in order to avoid a variation in the IGBT characteristics derived from the carbon concentration in the semiconductor substrate, would have influence on the diode characteristics in the diode part 102, such as the diode forward voltage Vf. To deal with this, the method of manufacturing the semiconductor device according to the first embodiment, which adjusts the preparation conditions for the collector region 9 formed only in the transistor part 101, can avoid a variation in the IGBT characteristics in the transistor part 101 while suppressing an influence on the diode characteristics in the diode part 102 without the number of the manufacturing steps increased.

### Second Embodiment

A semiconductor device according to a second embodiment has a configuration similar to that of the semiconductor device according to the first embodiment illustrated in FIG. 1 and FIG. 2. A method of manufacturing the semiconductor device according to the second embodiment differs from the method of manufacturing the semiconductor device according to the first embodiment in adjusting conditions for preparing the base region 3 in the transistor part 101 depending on the carbon concentration in the semiconductor substrate 10, instead of adjusting the conditions for preparing the collector region 9 in the transistor part 101.

For example, the conditions for preparing the base region 3, such as the dose amount of the ion implantation for forming the base region 3, are adjusted depending on the carbon concentration in the semiconductor substrate 10. The adjusted dose amount of the ion implantation can be set within about ±10% of the dose amount before the adjustment. As illustrated in FIG. 15, the base region 3 in the transistor part 101 and the anode region 13 in the diode part 102 are formed simultaneously by the common ion implantation. The adjusted dose amount, however, is quite small, and the influence on the diode characteristics of the diode part 102 is thus small.

When the dose amount of the ion implantation for forming the base region 3 is adjusted to be high, a gate threshold Vth is increased, and the collector-emitter saturation voltage Vce (sat) is increased while the turn-off loss Eoff is decreased. When the dose amount of the ion implantation for forming the base region 3 is adjusted to be low, the gate threshold Vth is decreased, and the collector-emitter saturation voltage Vce (sat) is decreased while the turn-off loss Eoff is increased.

In view of this, the method of manufacturing the semiconductor device according to the second embodiment adjusts the dose amount of the ion implantation for forming the base region 3 to be higher as the carbon concentration in the semiconductor substrate 10 is lower so as to decrease the turn-off loss Eoff and increase the collector-emitter saturation voltage Vce (sat). For example, when the carbon concentration in the semiconductor substrate 10 is relatively low and the turn-off loss Eoff thus could exceed the maximum standard value E1, the dose amount of the ion implantation for forming the base region 3 is adjusted to be high so that the turn-off loss Eoff is decreased to the maximum standard value E1 or smaller and the collector-emitter saturation voltage Vce (sat) is increased but regulated to be the maximum standard value V1 or smaller.

When the carbon concentration in the semiconductor substrate 10 is relatively high and the collector-emitter saturation voltage Vce (sat) thus could exceed the maximum standard value V1, the dose amount of the ion implantation for forming the base region 3 is adjusted to be low so that the collector-emitter saturation voltage Vce (sat) is decreased to the maximum standard value V1 or smaller and the turn-off loss Eoff is increased but regulated to be the maximum standard value E1 or smaller.

For example, a determination is made whether the carbon concentration in the semiconductor substrate 10 is a predetermined threshold or greater, and the dose amount of the ion implantation for forming the base region 3 is adjusted in accordance with the determination result. The predetermined threshold can be set depending on the rated current, the maximum standard value V1 of the collector-emitter saturation voltage Vce (sat), and the maximum standard value E1 of the turn-off loss Eoff of the semiconductor device according to the second embodiment, for example.

For example, when the carbon concentration in the semiconductor substrate 10 is the predetermined threshold or greater, the dose amount of the ion implantation for forming the base region 3 is set to a first dose amount before adjustment. When the carbon concentration in the semiconductor substrate 10 is less than the predetermined threshold, the dose amount of the ion implantation for forming the base region 3 is adjusted to a second dose amount greater than the first dose amount. Alternatively, several predetermined thresholds may be set and each compared with the carbon concentration in the semiconductor substrate 10 so that the dose amount is adjusted at several levels.

The other steps of the method of manufacturing the semiconductor device according to the second embodiment are common to those of the method of manufacturing the semiconductor device according to the first embodiment as described with reference to FIG. 11 to FIG. 19, and overlapping explanations are not repeated below.

The method of manufacturing the semiconductor device according to the second embodiment adjusts the conditions for preparing the base region 3 depending on the carbon concentration in the semiconductor substrate 10, instead of adjusting the conditions for preparing the collector region 9, so as to decrease defects. Further, the manufacturing method can suppress an influence on the contact resistance of the collector region 9 as compared with the case of adjusting the conditions for preparing the collector region 9.

Further, the method of manufacturing the semiconductor device according to the second embodiment, which adjusts the conditions for preparing the base region 3 in the transistor part 101 in the RC-IGBT, can reduce, to a smaller level, an influence on the diode characteristics in the diode part 102 including the anode region 13 formed simultaneously with the base region 3 without the number of the manufacturing steps increased, so as to avoid a variation in the IGBT characteristics in the transistor part 101.

While the method of manufacturing the semiconductor device according to the second embodiment is illustrated above with the case of adjusting the dose amount of the ion implantation for forming the base region 3, instead of adjusting the conditions for preparing the collector region 9, the manufacturing method may adjust an acceleration voltage upon the ion implantation for forming the base region 3 depending on the carbon concentration in the semiconductor substrate 10. For example, the acceleration voltage upon the ion implantation for forming the base region 3 is adjusted to be higher as the carbon concentration in the semiconductor substrate 10 is lower, so as to implant the impurity ions to a deeper part to decrease the gate threshold voltage Vth.

For example, a determination is made whether the carbon concentration in the semiconductor substrate 10 is a predetermined threshold or greater, and the acceleration voltage upon the ion implantation for forming the base region 3 is adjusted in accordance with the determination result. The predetermined threshold can be set depending on the rated current, the maximum standard value V1 of the collector-emitter saturation voltage Vce (sat), and the maximum standard value E1 of the turn-off loss Eoff of the semiconductor device according to the second embodiment. For example, when the carbon concentration in the semiconductor substrate 10 is the predetermined threshold or greater, the acceleration voltage upon the ion implantation for forming the base region 3 is set to a first acceleration voltage before adjustment. When the carbon concentration in the semiconductor substrate 10 is less than the predetermined threshold, the acceleration voltage upon the ion implantation for forming the base region 3 is adjusted to a second acceleration voltage greater than the first acceleration voltage. Alternatively, several predetermined thresholds may be set and each compared with the carbon concentration in the semiconductor substrate 10 so that the acceleration voltage is adjusted at several levels.

Alternatively, both the dose amount of the ion implantation for forming the collector region 9 and the dose amount of the ion implantation for forming the base region 3 may be adjusted depending on the carbon concentration in the semiconductor substrate 10. Alternatively, each of the dose amount of the ion implantation for forming the collector region 9, the dose amount of the ion implantation for forming the base region 3, and the acceleration voltage upon the ion implantation for forming the base region 3 may be adjusted depending on the carbon concentration in the semiconductor substrate 10.

### Other Embodiments

As described above, the invention has been described according to the first and second embodiments, but it should not be understood that the description and drawings implementing a portion of this disclosure limit the invention. Various alternative embodiments of the present invention, examples, and operational techniques will be apparent to those skilled in the art from this disclosure.

While the respective semiconductor devices according to the first and second embodiments are illustrated above with the RC-IGBT, the present invention can be applied to other IGBTs instead the RC-IGBT. The present invention may be applied to a single IGBT, for example. The present invention, when using a single IGBT, can also avoid a variation in the IGBT characteristics by adjusting at least the dose amount of either the collector region 9 or the base region 3.

Further, the configurations disclosed in the first and second embodiments may be combined as appropriate within a range that does not contradict with the scope of the respective embodiments. As described above, the invention includes various embodiments of the present invention and the like not described herein. Therefore, the scope of the present invention is defined only by the technical features specifying the present invention, which are prescribed by claims, the words and terms in the claims shall be reasonably construed from the subject matters recited in the present specification.

What is claimed is:

1. A method of manufacturing a semiconductor device, comprising:
forming a trench from a top surface side of a semiconductor substrate of a first conductivity-type;
burying an insulated gate electrode structure in the trench;
forming a base region of a second conductivity-type at an upper part of the semiconductor substrate so as to be in contact with the trench;
forming a first main electrode region of the first conductivity-type at an upper part of the base region so as to be in contact with the trench; and
forming a second main electrode region of the second conductivity-type on a bottom surface side of the semiconductor substrate,
wherein a preparation condition for at least either the base region or the second main electrode region is adjusted depending on a carbon concentration in the semiconductor substrate.

2. The method of manufacturing the semiconductor device of claim 1, wherein the preparation condition is a dose amount of ion implantation for forming the second main electrode region.

3. The method of manufacturing the semiconductor device of claim 1, wherein the preparation condition is a dose amount of ion implantation for forming the base region.

4. The method of manufacturing the semiconductor device of claim 2, wherein the dose amount is adjusted to be lower as the carbon concentration is lower.

5. The method of manufacturing the semiconductor device of claim 2, wherein the dose amount is adjusted to be lower when the carbon concentration is less than a threshold than when the carbon concentration is the threshold or greater.

6. The method of manufacturing the semiconductor device of claim 1, further comprising injecting a light element into the semiconductor substrate.

7. The method of manufacturing the semiconductor device of claim 6, wherein the light element is helium or proton.

8. The method of manufacturing the semiconductor device of claim 1, wherein the semiconductor device is a reverse conductive insulated gate bipolar transistor further including a diode part in the semiconductor substrate.

9. The method of manufacturing the semiconductor device of claim 8, comprising forming an anode region in the diode part simultaneously with the forming the base region.

10. The method of manufacturing the semiconductor device of claim 1, wherein the semiconductor substrate is manufactured by a magnetic field-applied Czochralski method.

11. The method of manufacturing the semiconductor device of claim 1, wherein the preparation condition is an acceleration voltage for forming the base region.
